(19) United States
(12) Patent Application Publication
(10) Pub. No.: US 2021/0066243 A1
(43) Pub. Date: Mar. 4, 2021

(54) MICRO LED DISPLAY AND METHOD FOR MANUFACTURING THE SAME

(71) Applicant: Samsung Electronics Co., Ltd., Suwon-si (KR)

(72) Inventors: Byunghoon LEE, Suwon-si (KR); Sungyong MIN, Suwon-si (KR); Changjoon LEE, Suwon-si (KR); Jamyeong KOO, Suwon-si (KR)

(21) Appl. No.: 17/010,231

(22) Filed: Sep. 2, 2020

(30) Foreign Application Priority Data
Sep. 3, 2019 (KR) 10-2019-0108845

(51) Int. Cl. H01L 23/00; H01L 25/16; H01L 25/075

(52) U.S. Cl. CPC H01L 24/95; H01L 2224/32238; H01L 25/0753; H01L 24/29; H01L 24/32; H01L 24/83; H01L 2224/95001; H01L 2224/29311; H01L 2224/29313; H01L 2224/29309; H01L 2224/29347; H01L 2224/29355; H01L 2224/29339; H01L 2224/29344; H01L 2224/29082; H01L 2224/29023; H01L 2224/32113; H01L 2224/32145; H01L 2224/83005; H01L 2224/83224; H01L 25/167

(57) ABSTRACT

A method for manufacturing a micro light emitting diode (LED) display is provided. The method includes a first operation of applying a light-to-heat conversion layer to a first surface of a carrier substrate, a second operation of forming a first adhesive layer on the light-to-heat conversion layer a third operation of aligning a plurality of micro LED chips on the first adhesive layer, a fourth operation of positioning the plurality of micro LED chips above a circuit board at a first distance, a fifth operation of radiating a laser to the plurality of micro LED chips, and a sixth operation of causing the first adhesive layer to be deformed by the light-to-heat conversion layer, so that the plurality of micro LED chips are detached from the first adhesive layer to be attached to the circuit board. Various other embodiments are possible.

### CROSS-REFERENCE TO RELATED APPLICATION(S)

This application is based on and claims priority under 35 U.S.C. 119(a) of a Korean patent application number 10-2019-0108845, filed on Sep. 3, 2019, in the Korean Intellectual Property Office, the disclosure of which is incorporated by reference herein in its entirety.

### BACKGROUND

### 1. Field

The disclosure relates to a micro light emitting diode (LED) display and a method for manufacturing the same.

### 2. Description of Related Art

In addition to the continuous development direction for high-luminance, high-resolution, and increase in size of displays mounted on various electronic devices, the demand for high-efficiency and low-power is recently increasing according to the trend of eco-electronic devices. Accordingly, organic light-emitting diode (OLED) panels have been spotlighted as a new display to replace liquid crystal display (LCD) panels, but there is a problem still remaining, relating to high price, increase in size, and reliability due to low mass production yield thereof.

As a new product to replace or supplement the OLED panels, studies on a technology to make display panels by directly mounting a light emitting diode (LED) emitting colors of red (R), green (G), and blue (B) on a substrate are being carried out.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a micro light emitting diode (LED) display which is suitable for connection of micro-sized micro LED chips and is applicable to a process for a large area with high throughput, and a method for manufacturing the same.

However, in order to realize such displays, subminiature micro LEDs that can respond to current pixels should be developed first, and problems relating to a method in which micro LED chips having a size of several tens of μm are picked, a degree of precision with which the chips are transferred onto a substrate, and a method in which electrodes having a size of several μm and located on the micro LED chips having a size of several tens of μm are electrically connected to the substrate should be firstly solved.

Another aspect of the disclosure is to provide a micro LED display in which micro LED chips can be transferred onto a circuit board at a high speed by using a light-to-heat conversion layer, and a method for manufacturing the same.

Another aspect of the disclosure is to provide a micro LED display in which ablation of an adhesive layer can be controlled by controlling a material and thickness of a light-to-heat conversion layer, and a method for manufacturing the same.

Additional aspects will be set forth in part in the description which follows and, in part, will be apparent from the description, or may be learned by practice of the presented embodiments.

In accordance with an aspect of the disclosure, a metal wire bonding method is provided. The method may be limitedly used due to a complicate process and low throughput thereof, and instability of a metal wire connecting a substrate and an element.

A flip-chip bonding method using solder bump, which is used to replace the metal wire bonding method, has several limitations. The flip-chip bonding method should be performed by patterning bumps on electrode one by one. Moreover, patterning bumps having a size of several μm is difficult.

In accordance with an aspect of the disclosure, a method for manufacturing a micro LED display is provided. The method includes a first operation of applying a light-to-heat conversion layer on a first surface of a carrier substrate, a second operation of forming a first adhesive layer on the light-to-heat conversion layer, a third operation of aligning a plurality of micro LED chips on the first adhesive layer, a fourth operation of positioning the plurality of micro LED chips at a first distance above a circuit board, a fifth operation of radiating a laser to the plurality of micro LED chips, and a sixth operation of causing the first adhesive layer to be deformed by the light-to-heat conversion layer, so that the plurality of micro LED chips are detached from the first adhesive layer to be attached to the circuit board.

According to the disclosure, electrode elements, for example, a micro LED chip, can be easily and electrically connected to a substrate through a simple process including bonding a conductive film containing conductive particles having a size of several μm or less, laser transfer, and curing.

According to the disclosure, a manufacturing process is very simple and thus can contribute to improving the yield of a process for a large area of a display element, for example, a micro LED display.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is an enlarged cross-sectional view illustrating a bonding state of a micro LED chip according to an embodiment of the disclosure;

FIG. 2A is a cross-sectional view for sequentially showing an operation of manufacturing a micro LED display according to an embodiment of the disclosure;

FIG. 2B is a cross-sectional view for sequentially showing an operation of manufacturing a micro LED display according to an embodiment of the disclosure;

FIG. 2C is a cross-sectional view for sequentially showing an operation of manufacturing a micro LED display according to an embodiment of the disclosure;

FIG. 3A is a cross-sectional view for sequentially showing an operation of manufacturing a micro LED display according to an embodiment of the disclosure;

FIG. 3B is a cross-sectional view for sequentially showing an operation of manufacturing a micro LED display according to an embodiment of the disclosure;

FIG. 4 is a cross-sectional view for sequentially showing an operation of manufacturing a micro LED display according to an embodiment of the disclosure;

FIG. 5 is an enlarged cross-sectional view illustrating an operation of transferring a micro LED chip during an operation of manufacturing a micro LED display according to an embodiment of the disclosure;

FIG. 6 is an enlarged cross-sectional view illustrating an operation of transferring a micro LED chip during an operation of manufacturing a micro LED display according to an embodiment of the disclosure;

FIG. 7 is an enlarged cross-sectional view illustrating an operation of transferring a micro LED chip during an operation of manufacturing a micro LED display according to an embodiment of the disclosure;

FIG. 8 is a plan view illustrating a micro LED display manufactured using a display manufacturing method according to an embodiment of the disclosure; and

FIG. 9 is a plan view illustrating a display having a large size screen, obtained by combining micro LED displays manufactured using a display manufacturing method according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and equivalents.

It is to be understood that the singular forms “a,” “an,” and “the” include plural referents unless the context clearly dictates otherwise. Thus, for example, reference to “a component surface” includes reference to one or more of such surfaces.

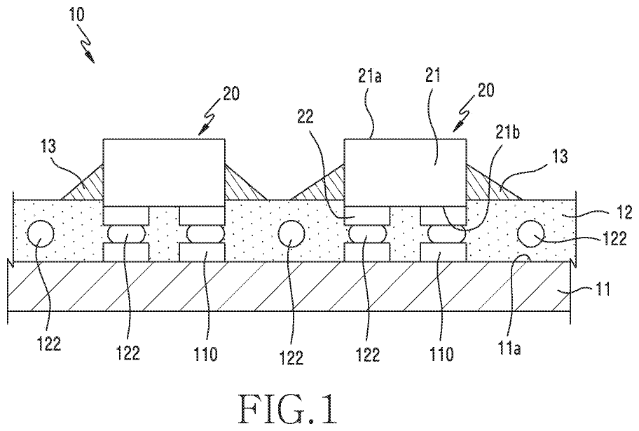

FIG. 1 is a cross-sectional view illustrating a structure of a micro LED display according to an embodiment of the disclosure.

Referring to FIG. 1, a display device 10 according to one embodiment, which functions as a display element using a structure in which a plurality of light emitting elements are arranged on a circuit board 11 and emit light, may be a display device having a plurality of chips, for example, micro LED chips 20 attached thereto. The display device 10 according to one embodiment may include the circuit board 11, a conductive film 12, an adhesive coating layer 13, and the plurality of micro LED chips 20.

According to one embodiment, the plurality of light emitting elements, for example, the micro LED chips 20, function as a light source of the display and may become conductive after being attached to the circuit board 11. For example, the micro LED chips 20 may have a size of approximately 100 μm or less, and may generally have a size ranging from several μm to several tens of μm.

According to one embodiment, the micro LED chips 20 may include a light emitting body 21 and a connection pad 22. According to one embodiment, one surface 21a of the light emitting body 21 may be a surface from which light is emitted, and the other surface 21b thereof may be a surface on which the connection pad 22 is disposed. According to one embodiment, the plurality of micro LED chips 20 may be attached in a connection pad-down state onto the conductive film 12. According to one embodiment, the connection pad 22 may be located within the conductive film 12 (anisotropic conductive film (ACF)) so that micro LED chips 20 may be disposed to be connected to a conductive particle 122. According to one embodiment, the conductive film 12 may be a double-sided adhesive film obtained by mixing a heat-curable adhesive and conductive particles disposed therein and having a fine particle size.

According to one embodiment, the circuit board 11 may be a support base for attaching a plurality of electrical elements, for example, the micro LED chips 20, used as a light emitting element of a display, to be aligned thereon. For example, the circuit board 11 may be formed of one of a glass material, a sapphire material, a synthetic resin, or a ceramic material. According to one embodiment, the circuit board 11 may be formed of a rigid material or a flexible material. According to one embodiment, a circuit part 110 formed of a conductive material, for example, an electrode, may be disposed on one surface 11a of the circuit board 11, to which the micro LED chips 20 are connected. For example, the circuit part 110 may be a thin film transistor (TFT) circuit or an indium tin oxide (ITO), or may be an upper layer disposed on the circuit board 11. According to one embodiment, the circuit part 110 may have a layer shape and be disposed one surface of the circuit board 11. According to one embodiment, the circuit part 110 may be disposed to protrude from one surface of the circuit board 11 or may be disposed to be recessed therefrom.

According to one embodiment, the conductive film 12 may be disposed on one surface of the circuit board 11. According to one embodiment, the conductive film 12, which functions as an adhesive layer for fixing the micro LED chips and connecting the micro LED chip and the circuit part to each other, may include a plurality of conductive particles 122 which are mutually dispersed. For example, each of the conductive particles 122 may have a size between 0.1 μm and 10 μm and preferably have a size of 5.5 μm or less. According to one embodiment, the conductive particles 122 may be disposed at equal intervals in the conductive film 12. According to one embodiment, among the plurality of conductive particles 122 included in the conductive film 12 (e.g., anisotropic conductive film), the conductive particles 122 located between the connection pad 22 and the circuit part 110 may be plastically deformed during the manufacturing process, and thus may not have a ball shape.

According to one embodiment, the at least one conductive particle 122 may be a conductive structure that electrically connects the connection pad 22 of the micro LED chip and the circuit part 110 of the circuit board 11 to each other.

According to one embodiment, the conductive film 12 may be a support structure for supporting the arranged micro LED chips 20, and the conductive film 12 may include the plurality of conductive particles 122, and thus may be a part of a conductive structure that electrically connects the micro LED chips 20 to the circuit part 110 of the circuit board 11.

According to one embodiment, a conductive structure of the micro LED chips 20 may be formed in the micro LED display (e.g., display device 10) by a structure in which the connection pad 22 of the micro LED chips 20, the plurality of conductive particles 122, and the circuit part 110 of the circuit board 11 are connected to one another. According to one embodiment, a part of the conductive particles 122 may be incorporated into the adhesive coating layer 13 coated on the conductive film 12.

According to one embodiment, the surface of the connection pad 22 or the circuit part 110 may be a transparent electrode, such as indium-tin-oxide (ITO), CNT, metal nanowire, graphene, and an adhesive metal deposition layer, such as Mo, Ti, and W, or may be formed of one of Au, Cu, Ni, Co, or a conductive polymer.

According to one embodiment, the adhesive coating layer 13 coated around each micro LED chip 20 may be cured and utilized as a bonding strength reinforcing structure. Hereinafter, the adhesive coating layer 13 will be referred to as a bonding strength reinforcing structure.

According to one embodiment, each micro LED chip 20 may include the bonding strength reinforcing structure (e.g., adhesive coating layer 13) that surrounds the side surface thereof. According to one embodiment, a bonding strength reinforcing structure (e.g., adhesive coating layer 13) may be attached to the side surface of each micro LED chip 20 while being attached to the anisotropic conductive film, so that the attachment state of each micro LED chip 20 can be fixed. For example, the bonding strength reinforcing structures (e.g., adhesive coating layer 13) may be spaced apart from each other or connected to each other.

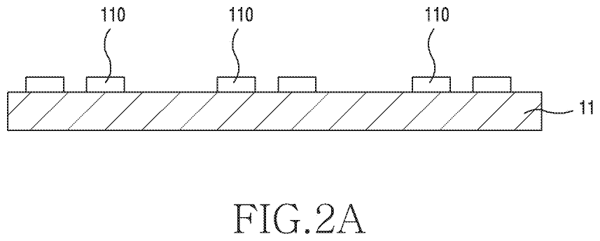

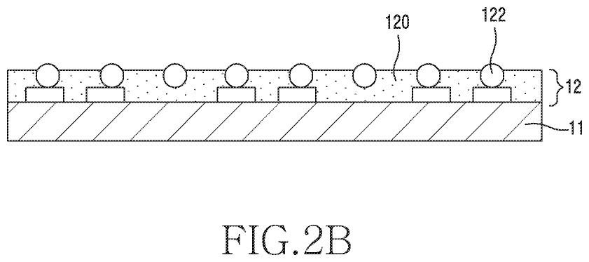

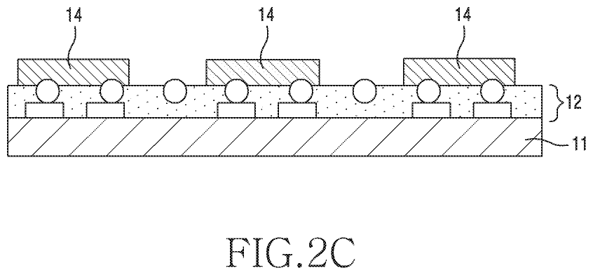

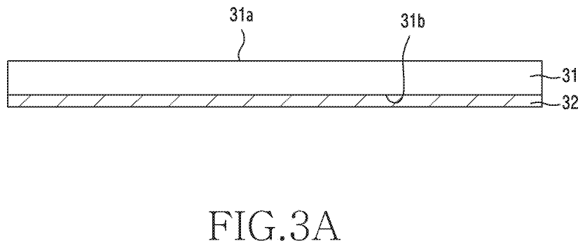

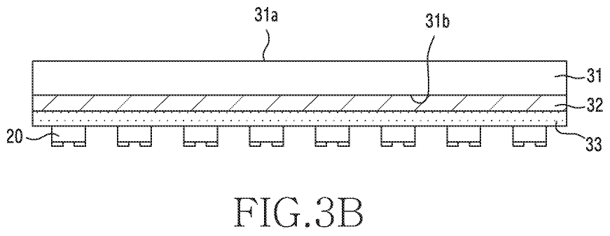

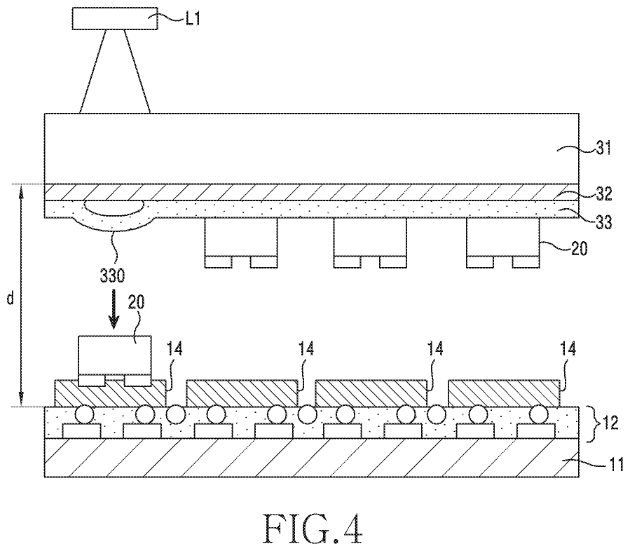

FIG. 2A is a cross-sectional view for sequentially showing an operation of manufacturing a micro LED display according to various embodiments, FIG. 2B is a cross-sectional view for sequentially showing an operation of manufacturing a micro LED display according to various embodiments, FIG. 2C is a cross-sectional view for sequentially showing an operation of manufacturing a micro LED display according to various embodiments, FIG. 3A is a cross-sectional view for sequentially showing an operation of manufacturing a micro LED display according to various embodiments, FIG. 3B is a cross-sectional view illustrating for sequentially showing an operation of manufacturing a micro LED display according to various embodiments, and FIG. 4 is a cross-sectional view for sequentially showing an operation of manufacturing a micro LED display according to various embodiments.

Referring to FIG. 2A, according to one embodiment, the prepared circuit board 11 may have the circuit part 110 disposed on one surface thereof. For example, the circuit part 110, which functions as an electrode formed on a circuit board, may be a TFT circuit. According to one embodiment, the circuit part 110 may be formed on one surface of the circuit board 11 by plating, depositing, or patterning a conductive material.

Referring to FIG. 2B, according to one embodiment, the conductive film 12 may be pre-bonded at a first thickness onto the prepared circuit board 11. According to one embodiment, the conductive film 12 may be attached to one surface of the circuit board 11 by heat and pressure. Accordingly, the conductive film 12 may be a bonding layer attached onto the circuit board 11.

According to one embodiment, the conductive film 12 may include an adhesive film 120 and the plurality of conductive particles 122 contained therein. For example, the plurality of conductive particles 122 may be arranged on the adhesive film 120 at equal intervals. For example, the plurality of conductive particles 122, which are metal particles, may include one of tin, bismuth, indium, copper, nickel, gold, or silver.

Referring to FIG. 2C, according to one embodiment, a second adhesive layer 14 may be formed by applying an adhesive onto the conductive film 12. According to one embodiment, the second adhesive layer 14 may be applied to a part or the entire of one surface of the circuit board 11. For example, when the second adhesive layer 14 is applied to a part of the circuit board 11, the second adhesive layer 14 may be disposed around the circuit part 110.

According to one embodiment, the second adhesive layer 14 may be a tacky layer which absorbs the kinetic energy of the plurality of micro LED chips 20 separated from the carrier substrate during the laser transfer process, prevents the positional displacement of the micro LED chips 20 attached thereon, and temporarily fixes the micro LED chips 20 thereto.

For example, the application of the second adhesive layer 14 onto the conductive film 12 may be performed by one of dispensing, jetting, stencil printing, screen printing, bar coating, rolling coating, gravure printing, and reverse-offset printing. The second adhesive layer 14 having a constant thickness may be disposed on the conductive film 12 by the various methods.

Referring to FIGS. 3A and 3B, according to one embodiment, the carrier substrate 31 on which the plurality of micro LED chips 20 are aligned and attached may include a first surface 31a and a second surface 31b facing in the opposite direction to the first surface 31a. According to one embodiment, the light-to-heat conversion layer (LTHC) 32 may be applied to the second surface 31b of the carrier substrate 31. The light-to-heat conversion layer 32 may be a layer in which light energy is converted into heat energy. According to one embodiment, the light-to-heat conversion layer 32 may cause ablation of a first adhesive layer 33 by applying heat generated by laser irradiation to the first adhesive layer 33. For example, the light-to-heat conversion layer 32 may be applied to the second surface 31b at a thickness of several tens of μm.

According to one embodiment, the light-to-heat conversion layer 32 may have a wavelength at which laser light can pass.

According to one embodiment, the first adhesive layer 33 may be applied to the light-to-heat conversion layer 32. According to an embodiment, the plurality of micro LED chips 20 may be attached by the first adhesive layer 33 onto the light-to-heat conversion layer 32 to be aligned thereon. For example, the plurality of aligned and attached micro LED chips 20 may have one of R-based color, G-based color, or B-based color.

According to one embodiment, the light-to-heat conversion layer 32 may control the temperature generated therefrom by changing a material or thickness thereof. The first adhesive layer 33 which is fused by the controllable light-to-heat conversion layer 32 may be controlled. Through this operation, the carrier substrate 31 to which the plurality of micro LED chips 20 are attached may be prepared.

Referring to FIG. 4, the carrier substrate 31 prepared as shown in FIG. 3B may be located above the circuit board to be spaced a first distance (d) therefrom. For example, the plurality of micro LED chips 20 may be located in a connection pad down state on the circuit board 11.

According to one embodiment, laser light may be radiated to one micro LED chip 20 from a laser (L1) disposed above the carrier substrate 31. According to one embodiment, the laser light may be converted from the light having light energy into the light having heat energy by the light-to-heat conversion layer (LTHC) 32, and the converted heat energy may be delivered to a part of the first adhesive layer 33, to which the one micro LED chip 20 is attached. The part of the first adhesive layer 33 may be fused by the delivered heat and thus a deformed part 330 may be produced therefrom. For example, the deformed part 330 may have a downward convex shape. According to one embodiment, the one micro LED chip 20 that has been attached to the first adhesive layer 33 may be separated therefrom by the deformation of the first adhesive layer 33 to be attached to the second adhesive layer 14. For example, the separated micro LED chip 20 may be moved by falling due to its own weight or jetting by ablation of the first adhesive layer 33.

According to one embodiment, the arranged micro LED chip 20 or the plurality of arranged micro LED chips 20 may be sequentially transferred onto the circuit board 11 by moving the carrier substrate 31 or the circuit board 11 back and forth or left and right.

According to one embodiment, the first distance (d) may be 150 μm or less and preferably 100 μm or less.

According to one embodiment, the carrier substrate 31 may be formed of a material through which a specific wavelength passes or a material through which the laser (L1) passes. For example, the material of the carrier substrate 31 may be a glass material, and the laser (L1) may be an infrared laser or an ultraviolet laser. Each micro LED chip 20 may be stably placed on the above-described second adhesive layer 14 in the order of R, G, and B. For example, primarily, the red (R)-based micro LED chips 20 may be disposed on the circuit board 11, secondly, the green (G)-based micro LED chips 20 may be placed on the circuit board 11, and subsequently, the blue (B)-based micro LED chips 20 may be disposed on the circuit board 11. When the operation of connecting and fixing the micro LED chips 20 is completed, a plurality of pixels configured by the plurality of RGBs may be arranged on the circuit board 11 at equal intervals.

According to one embodiment, the laser (L1) may be disposed fixedly or movably, and the circuit board 11 may also be disposed fixedly or movably. For example, if the laser (L1) is fixed, the circuit board 11 may be disposed movably, and if the laser (L1) is movable, the circuit board 11 may be disposed fixedly. According to one embodiment, when the laser (L1) is fixed, the circuit board 11 may be installed to be movable back and forth or to be movable left and right.

According to one embodiment, the micro LED chips 20 descending at a certain acceleration may be sequentially attached onto the second adhesive layer 14, and the micro LED chips 20 falling at a constant acceleration may be stably placed on the second adhesive layer 14. This is because the second adhesive layer 14 may serve as a cushion pad and a bonding of the micro LED chips 20.

According to one embodiment, heat and pressure may be applied by a chuck to the micro LED chips 20 stably placed on the second adhesive layer 14. According to one embodiment, the chuck which is not shown may descend to apply heat and pressure to the stably placed micro LED chips 20. At least one conductive particle 122 disposed between the connection pad 22 and the circuit part 110 may be plastically deformed according to the operation of the chuck. The at least one conductive particle 122 disposed between the connection pad 22 and the circuit part 110 may be pressed by the chuck, and thus may be deformed from the original spherical shape thereof into a flat shape.

According to one embodiment, the connection pad 22, the plastically deformed conductive particles 122, and the circuit part 110 may be electrically connected to one another, to form a conductive structure, that is, a connection structure of the micro LED chips 20. According to one embodiment, the plurality of micro LED chips 20 disposed on the second adhesive layer 14 may be electrically connected to the circuit board 11 by heating and pressing operations. The electrical connection medium between the connection pads of the micro LED chips 20 and the circuit board 11 may be a plurality of conductive particles (e.g., the conductive particles 122 shown in FIG. 1) included in a conductive film (e.g., the conductive film 12 shown in FIG. 1).

According to one embodiment, at least a part of the first adhesive layer 33 may be deformed by ablation phenomenon which may be occurred on parts in direct contact with the light-to-heat conversion layer 32. Heat may be delivered from the light-to-heat conversion layer 32 directly to the deformed part 330 and thus may cause ablation on the deformed part 330.

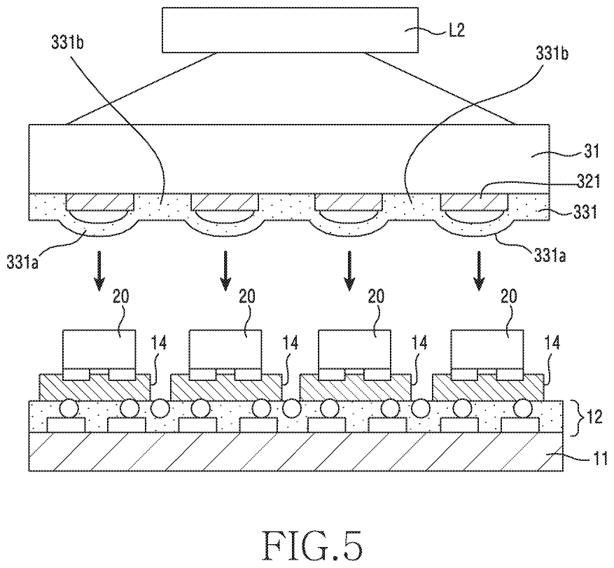

FIG. 5 is an enlarged cross-sectional view illustrating an operation in which a micro LED chip is transferred during an operation of manufacturing a micro LED display according to an embodiment of the disclosure.

Referring to FIG. 5, according to one embodiment, a light-to-heat conversion layer 321 and a first adhesive layer 331 for attaching a plurality of micro LED chips 20 to the light-to-heat conversion layer 321 may be included on one surface of the carrier substrate 31. According to one embodiment, at least one pattern may be formed on the light-to-heat conversion layer 321. According to one embodiment, the light-to-heat conversion layer 321 may enable selective irradiation of at least one attached micro LED chip 20 by using at least one pattern thereof.

According to one embodiment, the light-to-heat conversion layer 321 may have a pattern formed only on a part where the at least one micro LED chip 20 is attached, so that at least one micro LED chip 20 may be transferred onto the circuit board 11. For example, a laser (L2) light may be radiated only to a part where a pattern is formed so that light-to-heat change may be occurred on the part of the light-to-heat conversion layer 321. Accordingly, a deformed convex part 331a of the first adhesive layer 331 may be changed to be downward convex, and the at least one attached micro LED chip 20 may move toward the circuit board 11. The deformed convex part 331a may be distinguished from a part 331b of the first adhesive layer 331, which has no light-to-heat conversion layer and thus passes the laser (L2) light therethrough without reacting therewith.

A part of the first adhesive layer 331, that is, a part in contact with a part of the light-to-heat conversion layer 321 may be deformed by the light-to-heat change. For example, each of the deformed convex parts 331a may have a downward convex shape. The deformed convex part 331a may be a part having been fused by laser light.

According to one embodiment, the micro-LED chips 20 may be approximatively simultaneously separated from the first adhesive layer 331 to be attached onto the second adhesive layer 14 by irradiation from the laser (L2) to the plurality of micro-LED chips 20.

According to one embodiment, the plurality of micro LED chips 20 attached to and aligned on the first adhesive layer 331 may be simultaneously attached onto the second adhesive layer 14 by laser light irradiation.

According to one embodiment, at least one pattern formed on the light-to-heat conversion layer 321 may be formed through a photolithography process. For example, the pattern may be formed only on a desired part of the light-to-heat conversion layer 321, so that the micro LED chips 20 can be selectively transferred.

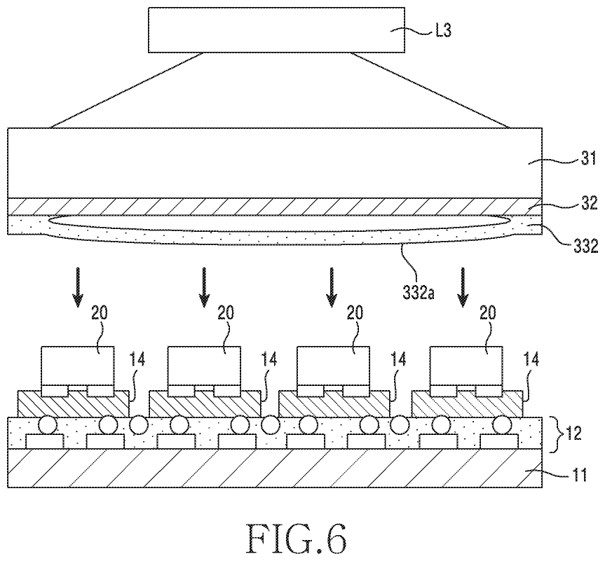

FIG. 6 is an enlarged cross-sectional view illustrating an operation in which a micro LED chip is transferred during an operation of manufacturing a micro LED display according to an embodiment of the disclosure.

Referring to FIG. 6, according to one embodiment, laser light may be radiated to the plurality of micro LED chips 20 from a laser (L3) disposed above the carrier substrate 31. According to one embodiment, the laser light may be converted from the light having light energy into the light having heat energy by the light-to-heat conversion layer 32, and the converted heat energy may be delivered to the first adhesive layer 332 to which the plurality of micro LED chips 20 are attached. The first adhesive layer 332 may be fused by the delivered heat and thus a deformed part 332a may be produced therefrom. For example, the deformed part 332a may have a downward convex shape. For example, the downward direction may be a direction toward the circuit board 11.

According to one embodiment, the plurality of micro LED chips 20 that have been attached to the first adhesive layer 332 may be separated therefrom by the deformation of the first adhesive layer 332 and be attached to the second adhesive layer 14. For example, the separated micro LED chip 20 may be moved by falling due to its own weight or jetting by ablation of the first adhesive layer 332.

According to one embodiment, the plurality of arranged micro LED chips 20 may be transferred to the circuit board 11 by moving the carrier substrate 31 or the circuit board 11 back and forth or left and right.

According to one embodiment, since an area from which the laser L3 can be radiated is infinite, the micro LED chips 20 that can be transferred at once may be infinite as the irradiation area of the light-to-heat conversion layer 32 is increased.

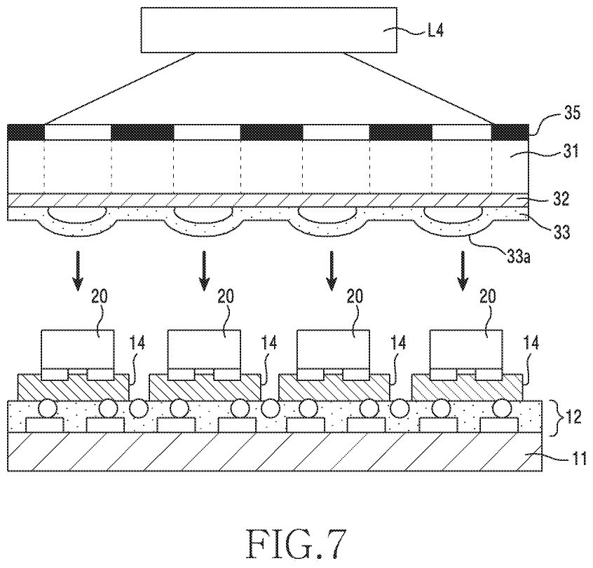

FIG. 7 is an enlarged cross-sectional view illustrating an operation in which a micro LED chip is transferred during an operation of manufacturing a micro LED display according to an embodiment of the disclosure.

Referring to FIG. 7, according to one embodiment, a mask 35 may be disposed between the carrier substrate 31 and a laser (L4). According to one embodiment, the laser (L4) may be selectively radiated to the micro LED chip 20 by the mask 35 so that some light therefrom passes through the mask 35 and some light therefrom does not pass through the mask. For example, some of light radiated from the laser (L4) may pass through the mask 35 and be irradiated to the first adhesive layer 33.

According to one embodiment, laser light may be converted from the light having light energy into the light having heat energy by the light-to-heat conversion layer 32, and the converted heat energy may be delivered to the first adhesive layer 33 to which the plurality of micro LED chips 20 are attached. The first adhesive layer 33 may be fused by the delivered heat and thus a plurality of deformed parts 33a may be produced therefrom. For example, each of the deformed parts 33a may have a downward convex shape. According to one embodiment, the plurality of micro LED chips 20 that have been attached to the first adhesive layer 33 may be separated therefrom by the deformation of the first adhesive layer 33 and be attached to the second adhesive layer 14. For example, the separated micro LED chip 20 may be moved by falling due to its own weight or jetting by ablation of the first adhesive layer 33.

According to one embodiment, the irradiation from the laser (L4) using the mask 35 may enable simultaneous and selective transferring of the plurality of micro LED chips 20.

According to one embodiment, the plurality of arranged micro LED chips 20 may be sequentially transferred to the circuit board 11 by moving the carrier substrate 31 or the circuit board 11 back and forth or left and right.

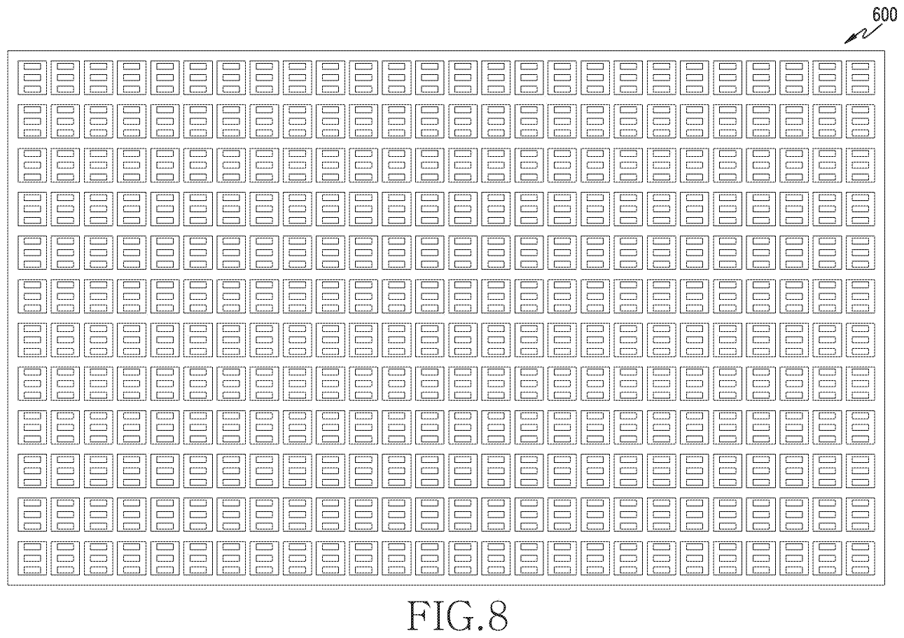

FIG. 8 is a plan view illustrating a micro LED display manufactured using a display manufacturing method according to an embodiment of the disclosure.

Referring to FIG. 8, a componentized micro LED display 600 may be mounted on a main board and manufactured as a large screen display, and may be manufactured as displays having various sizes.

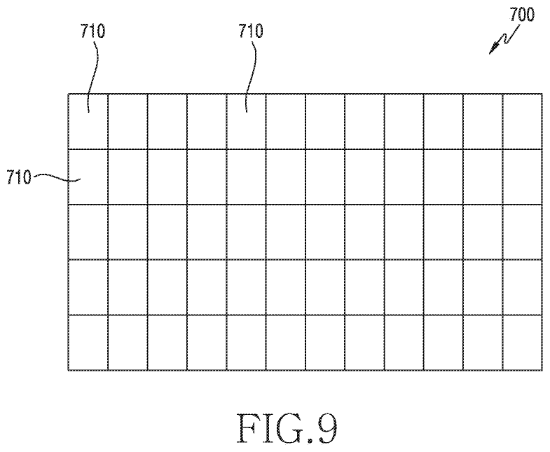

FIG. 9 is a plan view illustrating a display having a large size screen, obtained by combining micro LED displays manufactured using a display manufacturing method according to an embodiment of the disclosure.

Referring to FIG. 9, a micro LED display 700 having various wide-widths (e.g., a large TV or a billboard, etc.) may be manufactured by assembling a plurality of micro LED displays 710 manufactured through the manufacturing operations illustrated in FIGS. 2A to 4.

While the disclosure has been shown and described with reference to various embodiments thereof, it will be understood by those skilled in the art that various changes in form and details may be made therein without departing from spirit and scope of the disclosure as defined by the appended claims and their equivalents.

What is claimed is:

1. A method for manufacturing a micro light emitting diode (LED) display, the method comprising:
a first operation of applying a light-to-heat conversion layer to a first surface of a carrier substrate;
a second operation of forming a first adhesive layer on the light-to-heat conversion layer;
a third operation of aligning a plurality of micro LED chips on the first adhesive layer;
a fourth operation of positioning the plurality of micro LED chips above a circuit board at a first distance;
a fifth operation of radiating a laser to the plurality of micro LED chips; and
a sixth operation of causing the first adhesive layer to be deformed by the light-to-heat conversion layer, so that the plurality of micro LED chips are detached from the first adhesive layer to be attached to the circuit board.

2. The method of claim 1, wherein the light-to-heat conversion layer converts light energy into heat energy to cause deformation of the first adhesive layer to which each of the micro LED chips is attached.

3. The method of claim 2, wherein a deformed part of the first adhesive layer has a downward convex shape.

4. The method of claim 1,
wherein the circuit board comprises:
a conductive film disposed on one surface thereof and including a plurality of conductive particles; and
a second adhesive layer applied onto the conductive film, and
wherein the plurality of micro LED chips are attached to the second adhesive layer.

5. The method of claim 1, wherein the first distance is 150 μm or less.

6. The method of claim 4, wherein in the sixth operation, the plurality of micro LED chips are transferred onto the second adhesive layer by the deformation of the first adhesive layer.

7. The method of claim 4, wherein the second adhesive layer absorbs kinetic energy of the plurality of micro LED chips separated from the carrier substrate, and temporarily fixes the plurality of micro LED chips thereto.

8. The method of claim 4, wherein the plurality of conductive particles comprises one of tin, bismuth, indium, copper, nickel, gold, or silver.

9. The method of claim 1, wherein the laser or the circuit board is movable left and right or back and forth.

10. The method of claim 1, wherein the carrier substrate has a wavelength at which laser light can pass.

11. The method of claim 1, wherein each of the circuit board and the carrier substrate is formed of one material of glass, ceramic, or a synthetic resin.

12. The method of claim 1, wherein the light-to-heat conversion layer comprises at least one pattern, and the micro LED chips are selectively irradiated by the at least one pattern.

13. The method of claim 1, wherein a mask is disposed on a second surface opposite to the first surface of the carrier substrate, and the micro LED chips are selectively irradiated by the mask.

14. The method of claim 1, wherein the laser can be radiated to a single micro LED chip of the plurality of micro LED chips or the plurality of the micro LED chips.

15. The method of claim 1, wherein the deformation of the first adhesive layer is controlled by changing a material and thickness of the light-to-heat conversion layer.

16. The method of claim 1, wherein the light-to-heat conversion layer converts light of the laser into heat.

17. The method of claim 16, wherein at least a part of the first adhesive layer attached to the light-to-heat conversion layer is fused, and then a downward convexly deformed part is produced therefrom.

18. The method of claim 17, wherein the first adhesive layer comprises at least one deformed part formed thereon.

19. A micro light emitting diode (LED) display comprising:
a circuit board;
a conductive film bonded to one surface of the circuit board and comprising a plurality of conductive particles;
a plurality of micro LED chips attached onto the conductive film; and
a conductive structure formed between a connection pad of each of the plurality of micro LED chips and a circuit part by the plurality of conductive particles.

20. The display of claim 19, wherein the plurality of conductive particles are plastically deformed and become a part of the conductive structure.

21. The display of claim 19, wherein the plurality of conductive particles are disposed in substantially equal intervals in the conductive film.

22. The display of claim 19, wherein the circuit part comprises a protruding portion of the circuit board.

23. The display of claim 19, wherein the conductive film comprises an anisotropic conductive film.
